(19) United States
(12) Patent Application Publication
(10) Pub. No.: US 2015/0138885 A1
(43) Pub. Date: May 21, 2015

(54) NON-VOLATILE SEMICONDUCTOR STORAGE DEVICE, AND SEMICONDUCTOR DEVICE

(71) Applicant: KABUSHIKI KAISHA TOSHIBA, Tokyo (JP)

(72) Inventors: Hitoshi IWAI, Kanagawa (JP); Hiroshi SUKEGAWA, Tokyo (JP); Naoya TOKIWA, Kanagawa (JP)

(73) Assignee: KABUSHIKI KAISHA TOSHIBA, Tokyo (JP)

(21) Appl. No.: 14/191,281

(22) Filed: Feb. 26, 2014

(30) Foreign Application Priority Data
Nov. 15, 2013 (JP) 2013-237448

(51) Int. Cl. G11C 29/04; G11C 16/08

(52) U.S. Cl. CPC G11C 29/04; G11C 16/08
USPC 365/185.09

(57) ABSTRACT

A non-volatile semiconductor storage device includes a memory cell array divided into blocks, each of which is a erasable unit, the blocks, the blocks including a first block which is determined to be a bad block and a second block which is determined to be a partial bad block, a storage unit configured to store address information of the first block and the second block, and a block decoder including a latch section which is configured to control selection and non-selection of the blocks, and to release data held by the latch section based on the stored address information of the second block.

### CROSS-REFERENCE TO RELATED APPLICATION

This application is based upon and claims the benefit of priority from Japanese Patent Application No. 2013-237448, filed Nov. 15, 2013, the entire contents of which are incorporated herein by reference.

### FIELD

Embodiments described herein relate generally to a non-volatile semiconductor storage device, and a semiconductor device.

### BACKGROUND

Recently, a semiconductor memory has been developed in which memory cells are stacked (e.g., BiCS: Bit Cost Scalable Flash Memory) where memory cells are stacked. With such a configuration, a semiconductor memory having a large capacity may be realized at low cost.

### DESCRIPTION OF THE DRAWINGS

FIG. 1 is a view showing the overall configuration of a semiconductor device according to a first embodiment.

FIG. 2A is a plan view of a memory plane in the first embodiment.

FIG. 2B is a schematic diagram showing a partial good block in the first embodiment.

FIG. 3 is a circuit diagram of a block decoder in the first embodiment.

FIG. 4 is a cross-sectional view of a sub block in the first embodiment, and is a schematic diagram showing a storing state of failure information.

FIG. 5 is a view showing a method of determining a partial good block in the first embodiment.

FIG. 6 is a schematic diagram of a ROM FUSE in the first embodiment.

FIG. 7 is a view showing a method of resetting a block decoder, according to an embodiment.

FIG. 8 is a view showing a reading method according to an embodiment.

### DETAILED DESCRIPTION

Embodiments provide a non-volatile semiconductor storage device and a semiconductor device that effectively uses a failure region.

In general, according to one embodiment, a non-volatile semiconductor storage device includes a memory cell array divided into blocks, each of which is a erasable unit, the blocks, the blocks including a first block which is determined to be a bad block and a second block which is determined to be a partial bad block, a storage unit configured to store address information of the first block and the second block, and a block decoder including a latch section which is configured to control selection and non-selection of the blocks, and to release data held by the latch section based on the stored address information of the second block.

A non-volatile semiconductor storage device according to this embodiment effectively utilizes a user data region by using a good region, when such a good region exists in the block BLK even if only partially.

In the non-volatile semiconductor storage device according to this embodiment, a marking for indicating which region in a block BLK is a region corresponding to a failure region is written before shipping in a select transistor ST as information indicating failure (hereinafter referred to as “failure information”). The select transistor ST makes up a part of a memory string MS.

Next, by reading information stored in the select transistor ST after shipping, when a partial region of the block BLK may be used although the block BLK is a bad block as a whole, writing of data in the partial region is executed.

### Exemplary Embodiment

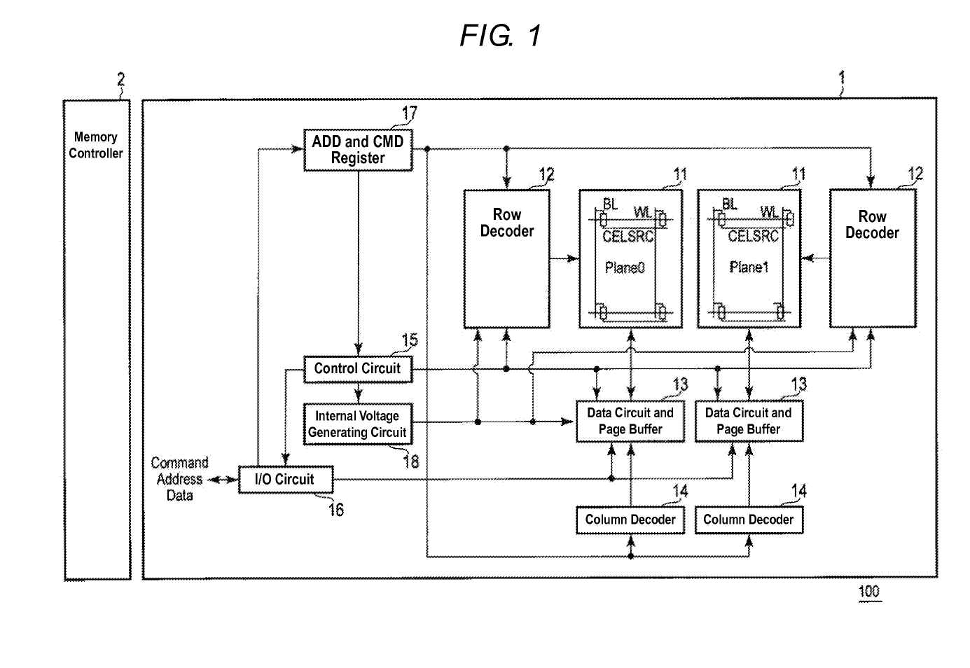

A first embodiment is described with reference to FIG. 1. FIG. 1 is a schematic diagram showing the overall configuration of a semiconductor device according to the first embodiment.

### 1. Overall Configuration Example

The overall configuration of a semiconductor device 100 according to the first embodiment is described with reference to FIG. 1. FIG. 1 is a block diagram of the semiconductor device 100 according to the first embodiment.

The semiconductor device 100 includes a non-volatile semiconductor storage device 1 and a memory controller 2 which controls the non-volatile semiconductor storage device 1.

As shown in FIG. 1, the non-volatile semiconductor storage device 1 according to the first embodiment includes: memory cell arrays 11; row decoders 12; data circuit and page buffers 13; column decoders 14; a control circuit 15; an input and output circuit 16; an address and command register 17; and an internal voltage generating circuit 18.

### <Memory Cell Array 11>

As shown in FIG. 1, the memory cell arrays 11 include a Plane 0 and a Plane 1 (expressed as Plane 0 and Plane 1 in FIG. 1) respectively, for example. The Plane 0 and the Plane 01 respectively include a plurality of memory strings MS. Bit lines BL, word lines WL, and source lines CELSRC are electrically connected to the memory strings MS.

The memory string MS includes a plurality of memory cells MC which are connected to each other in series, and the above-mentioned word line WL is connected to a control gate CG.

Here, the explanation is made with respect to the case where the Plane 0 and the Plane 1 are provided for the memory cell array 11. However, the number of memory planes for the memory cell array 11 is not limited. When it is unnecessary to distinguish the Plane 0 and the Plane 1 from each other, these planes 0, 1 are simply described as “Plane 0”.

### <Row Decoder 12>

The row decoder 12 (also referred to as “block decoder 12” hereinafter when appropriate) is described with reference to FIG. 1. The row decoder 12 includes a block decoder BD, and transfer transistors, Xfer_S and Xfer_D, which are described later.

The row decoder 12 decodes a block address signal or the like input from the address and command register 17, and selects a desired word line WL corresponding to the result of decoding. A voltage generated by the internal voltage generating circuit 18 is applied to the selected word line WL.

### <Data Circuit and Page Buffer 13>

The data circuit and page buffer 13 includes a sense amplifier SA (not shown) and a data cache DC (not shown). That is, the data circuit and page buffer 13 performs reading and writing of data, the transfer of read data to the outside and the intake of write data, using the sense amplifier SA and the data cache DC.

Reading of data is specifically described. When a command for executing a reading operation is input to the control circuit 15, the data circuit and page buffer 13 reads data held in the selected memory cell MC.

Thereafter, the data circuit and page buffer 13 outputs the read data to the memory controller 2 through the data cache DC and the input and output circuit.

Writing of data is specifically described.

The non-volatile semiconductor storage device 1 receives a command and an address for loading write data transferred from the memory controller 2 and, subsequently, receives write data.

The data circuit and page buffer 13 receives the write data through the input and output circuit 16 and intakes the write data into the data cache DC.

Thereafter, the write data is written in the selected memory cell MC through the data cache DC and the sense amplifier SA at a timing in accordance with an instruction from the control circuit 15.

### <Column Decoder 14>

The column decoder 14 decodes a column address signal input from the address and command register 17, and selects the column direction of the memory cell array 11.

### <Control Circuit 15>

The control circuit 15 controls an operation of the entire non-volatile semiconductor storage device 1. That is, the control circuit 15 executes an operation sequence upon executing a data write operation, a data reading operation, and a data erase operation based on a control signal, a command, and an address supplied from the address and command register 17.

To execute such a sequence, the control circuit 15 controls operations of respective circuit blocks included in the non-volatile semiconductor storage device 1. For example, the control circuit 15 controls the internal voltage generating circuit 18 so that the internal voltage generating circuit 18 generates a predetermined voltage, and the control circuit 15 controls a predetermined timing at which a predetermined voltage is output to the word lines WL and the bit lines BL through the row decoder 12 and the data circuit and page buffer 13. Further, the control circuit 15 is also concerned with a control of an input and an output state of the input and output circuit 16.

### <Input and Output Circuit 16>

The input and output circuit 16 receives a command, an address and write data from an external host equipment (not shown) and supplies the command and address to the address and command register 17, and supplies the write data to the data circuit and page buffer 13.

Further, the input and output circuit 16 outputs read data supplied from the data circuit and page buffer 13 to the host equipment in response to a control by the control circuit 15.

### <Address and Command Register 17>

The address and command register 17 temporarily holds a command and an address supplied from the input and output circuit 16 and, subsequently, supplies the command to the control circuit 15 and supplies the address to the row decoder 12 and the column decoder 14.

To be more specific, the address and command register 17 supplies a column address to the column decoder 14. The column decoder 14 corresponding to the column address is in a selected state so that data having predetermined address is output to the input and output circuit 16. The data output to the input and output circuit 16 is output to the external host equipment in response to a read enable signal.

### <Internal Voltage Generating Circuit 18>

The internal voltage generating circuit 18 generates predetermined voltages in a reading operation based on a control by the control circuit 15. For example, in the reading operation, the internal voltage generating circuit 18 generates a voltage VCGR and a voltage VREAD, and supplies the voltage VCGR to the selected word lines WL and supplies the voltage VREAD to the non-selected word lines WL.

The voltage VCGR is a voltage supplied to the memory cell MC to be read.

As one example, a value of the voltage VCGR when data held by a select transistor ST1 described later is read is set to 0 V, for example.

The voltage VREAD is a pass voltage which is applied to the non-selected word lines WL in the selected memory string MS and may bring the memory cell MC into an ON state without depending on the data held therein.

### 1. 2<Plan View of Plane 0>

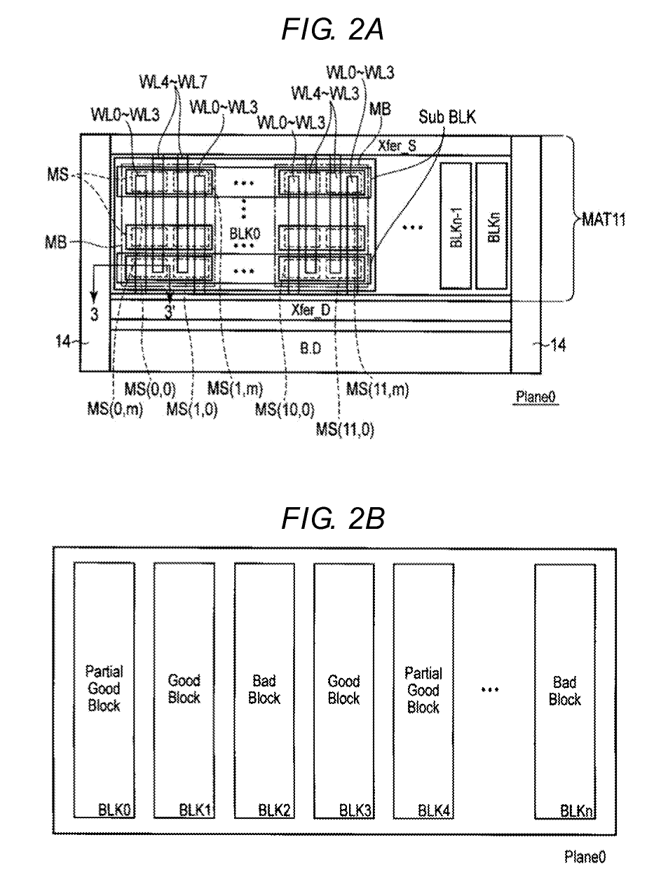

FIG. 2A is a plan view (top plan view) of the Plane 0, for example. Since the Plane 1 and the Plane 0 have the same configuration, the explanation of the Plane 1 is omitted in this embodiment.

For the sake of convenience of explanation, in addition to the plan view of the Plane 0, the row decoders 12 (in the drawing, transfer transistors, XFER_S and XFER_D, a block decoder (in the drawing, B.D)), and column decoders COL (in the drawing, C.D 14) are illustrated.

The Plane 0 includes a plurality of the memory cells MC. The memory string MS (in FIG. 2A, expressed as MS) includes eight memory cells MC which are connected to the word lines WL0 to WL7.

For example, the sub block (in the drawing, Sub BLK) includes a plurality of the memory strings MS (for example, 12 memory strings MS).

In this case, the memory strings MS which are connected to a bit line BL0 (not shown) are expressed as memory strings MS (0, 0), (1, 0), . . . , (10, 0) and (11, 0) hereinafter, and the memory strings MS0 which are connected to a bit line BLm are expressed as memory strings MS (0, m), (1, m), . . . , (10, m) and (11, m) hereinafter.

A set of memory strings MS0, MS1, a set of memory strings MS2, MS3, . . . , or a set of memory strings MS10, MS11 in the direction along the word lines WL is referred to as a memory block MB.

When the sub block includes 12 memory strings MS, 6 memory blocks MB are constituted in one block BLK.

The memory strings MS0 which are respectively connected to bit lines BL0, BL1, BL2, . . . , and BLm is referred to as a memory string unit MU, for example. The memory strings MS1 to the memory string MS11 also have the same configuration as the memory strings MS0 and hence, the explanation of the memory strings is omitted.

In the Plane 0, the word lines WL0 to WL3 (hereinafter, referred to as first signal line group) and the word lines WL4 to WL7 (hereinafter, referred to as second signal line group) are formed in a comb-teeth shape, and a semiconductor layer SC described later is formed so as to penetrate the respective memory strings MS in the depth direction with respect to a surface of paper on which FIG. 2A is drawn. The memory cell MC is formed on an intersection of the word line WL and the semiconductor layer SC.

As shown in the drawing, the XFER_D and the XFER_S are arranged in the second direction. One ends of the word lines WL0 to WL3 are connected to the XFER_D, and one ends of the word lines WL4 to WL7 are connected to the XFER_S.

The XFER_D and the XFER_S respectively include a plurality of MOS transistors, and select any one of the memory strings MS in the block BLK. To be more specific, upon receiving a decoder result from the block decoder BD, the XFER_D and the XFER_S may select the memory strings MS which are write targets or read targets.

The block decoder BD switches an ON state and an OFF state of the MOS transistors in the XFER_S and the XFER_D, and selects the memory string MS which are write targets or read targets from the plurality of memory strings MS.

The block decoder BD includes a latch section (described later) which holds a flag used for determining whether or not the block BLK is to be selected therein. When a voltage level of data held by the latch section is “H” level, the block BLK is in a selected state.

On the other hand, when the voltage level of data held by the latch section is “L” level, the block BLK is in a non-selected state.

The column decoder COL selects bit lines BL, which are not shown.

### 1. 3<Schematic Diagram of Partial Good Blocks>

The partial good blocks are described with reference to FIG. 2B. FIG. 2B is a schematic diagram showing the partial good blocks.

As shown in FIG. 2B, a block BLK1 and a block BLK3 are good blocks BLK, while a block BLK2 and a block BLKn are bad blocks.

There may also exist blocks which include a failure region in a partial region thereof. Such blocks are referred to as partial good blocks hereinafter.

In this embodiment, the block BLK0 and the block BLK4 are the partial good blocks. Although described above, in this embodiment, even when the block includes a region by which the block is basically determined as the bad block, provided that the block partially includes a good region, the good region is used. Such a block is referred to as the partial good block.

1. 4<Cross-Sectional View of Sub Block BLK, Schematic Diagram Showing a State where Failure Information is Held>

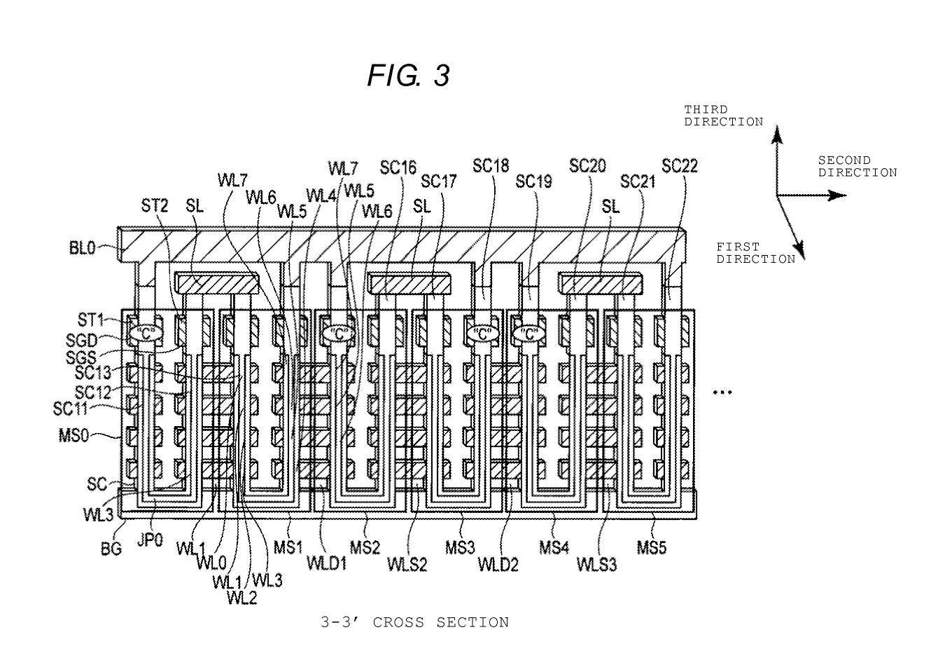

Next, the explanation is made with reference to FIG. 3 which is a cross-sectional view of a sub block SB0 taken along a line 3-3′ in FIG. 2 described above, and is a schematic diagram where the sub block holds failure information on the memory string MS. That is, FIG. 3 is a cross-sectional view of the block BLK0 in FIG. 2B.

As described above, failure information on the memory string MS is held by the select transistor ST which is part of the memory string MS. As described above, the sub block SB0 includes 12 memory strings MS, that is, the memory strings MS0 to MS11. However, in the drawing, for the sake of convenience, the memory strings MS0 to MS5 are shown.

### <1. 4. 1> in Re Memory Strings MS0 to MS5

As shown in FIG. 3, the memory strings MS0 to MS5 (indicated by bold frames) are arranged along the cross-sectional direction.

In each memory string MS, columnar semiconductor layers SC11, SC12 are formed on the semiconductor layer BG in such a manner that the semiconductor layers SC11, SC12 extend in a third direction orthogonal to a first direction and a second direction. Hereinafter, when it is not necessary to distinguish the semiconductor layers SC11 and SC12 from each other, the semiconductor layers SC11, SC12 are simply referred to as the semiconductor layer SC.

Next, the semiconductor layers SC which are adjacent to each other in the first direction are joined to each other by way of a joint portion JP arranged in the semiconductor layer BG. For example, the semiconductor layers SC11 and SC12 are joined to each other by way of the joint portion JP0 in the semiconductor layer BG. Due to such a configuration, the memory string MS0 having a U-shape is formed.

Besides the set of semiconductor layers SC11 and SC12, other sets of semiconductor layers such as a set of semiconductor layers SC13 and SC14, . . . and a set of semiconductor layers SC21 and SC22 also have the same configuration and hence, the explanation of these other sets of semiconductor layers is omitted.

A plurality of polysilicon layers which are formed along the third direction are provided for each memory string MS. Some polysilicon layers function as the word lines WL, and other polysilicon layers function as selection signal lines SGS, SGD.

The selection signal lines SGS, SGD are arranged at positions where the selection signal lines SGS, SGD sandwich the word lines WL. That is, as shown in FIG. 3, assuming that the number of word lines WL is 4, the word lines WL3, WL2, WL1, WL0 and the selection signal line SGS are stacked on the semiconductor layer BG in this order from below with an insulation film interposed therebetween. In the same manner, the word lines WL4, WL5, WL6, WL7 and the selection signal line SGD are stacked on the semiconductor layer BG in this order from below with an insulation film interposed therebetween.

Accordingly, the select transistor ST1, the memory cell MC7, the memory cell MC6, . . . , the memory cell MC1, the memory cell MC0, and the select transistor ST2 are provided to intersections of the semiconductor layer SC and the respective selection signal lines SGS, SGD, and the word lines WL.

The selection signal lines SGS, SGD function as the selection signal lines SGS, SGD which control the selection and the non-selection of the memory string MS.

The configuration of the memory cell array 11 is described in U.S. patent application Ser. No. 12/407,403 filed on Mar. 19, 2009 (three-dimensionally laminated non-volatile semiconductor memory), for example. Further, the configuration of the memory cell array 11 is also described in U.S. patent application Ser. No. 12/406,524 filed on Mar. 18, 2009 (three-dimensionally laminated non-volatile semiconductor memory), U.S. patent application Ser. No. 12/679,991 filed on Mar. 25, 2010 (non-volatile semiconductor storage device and method of manufacturing the same), and U.S. patent application Ser. No. 12/532,030 filed on Mar. 23, 2009 (semiconductor memory and method of manufacturing the same). The entire contents of the above-mentioned patent applications are incorporated herein by reference.

### <1. 4. 2> in Re Bit Line BL, Source Line SL

One end of the selection signal line SGD, one ends of the semiconductor layers SC11 and SC14, one ends of the semiconductor layers SC15 and the SC18, and one ends of the semiconductor layers SC19 and SC22 which penetrate the selection signal lines SGD are respectively connected to the bit line BL0.

One end of the selection signal line SGS, one ends of the semiconductor layers SC12 and SC13, one ends of the semiconductor layers SC16 and the SC17, and one ends of the semiconductor layer SC20 which respectively penetrate the selection signal lines SGS are respectively connected to the source lines SL. That is, for example, the semiconductor layers SC11, SC12 and the semiconductor layers SC13, SC14 which are adjacent to each other are connected in common to the source line SL.

### <1. 4. 3> in Re Bit Lines BL1 to BLm−1

Although the explanation has been made by focusing on the bit line BL0 heretofore, the configurations of the bit lines BL1 to BLm−1 are substantially the same as the configuration of the bit line BL0.

That is, it is assumed that the semiconductor layers SC which are connected to the bit lines BLi (i: natural number, 1≦i≦m−1) as semiconductor layers SCi1 to SC (i+10). In this case, the above-mentioned selection signal line SGS, word lines WL0 to 7, and selection signal line SGD penetrate the respective semiconductor layers SCi1 to SC (i+10) and hence, a plurality of memory strings MS are formed corresponding to the respective bit lines BLi.

Also in the respective memory strings MS corresponding to the bit line BLi, the semiconductor layers SCi1, SCi2 and the semiconductor layers SCi3, SCi4 which are adjacent to each other are connected in common to the source line SL.

Although the explanation has been made where each memory string MS includes the memory cells MC0 to MC7 and the select transistors ST1, ST2 as an example, the number of memory cells MC is not limited. That is, the number of memory cells MC may be set to 16 or 32. Hereinafter, there may be described a case where the number of memory cells MC is set to s (s: natural number).

As described above, the Plane 0 is configured by arranging the memory cells MC which electrically store data in a three-dimensional matrix array. That is, the memory cells MC are arranged in the stacking direction as well as in the horizontal direction orthogonal to the stacking direction in a matrix array. The plurality of memory cells MC which are arranged in the stacking direction are connected to each other in series, and the memory string MS includes the plurality of memory cells MC connected in series.

<1. 4. 4> Schematic Diagram Showing a State where Failure Information is Held

As shown in FIG. 3, the select transistor ST1 may hold information of 1 bit, that is, “0” or “1”. Information of 1 bit means that the information is at either one of threshold levels, that is, “E” (=“1”) level or “C” level (=“0”) (>“E” level).

“E” level means an erase state. When the memory cell MC is at an initial state, a threshold voltage is positioned at an erase state.

In this embodiment, when a memory string unit MU is a failure region, data held by the select transistor ST1 corresponding to the memory string unit MU is increased to a threshold voltage of “C” level. On the other hand, when the string unit MU is a good region, a threshold voltage of the select transistor ST1 is in an initial state, that is, “E” level.

To given an example using the configuration shown in FIG. 3, the select transistors ST1 constituting the memory strings MS0, MS2, MS3 and MS4 connected to the bit line BL0 hold data “C”.

That is, in the configuration example shown in FIG. 3, the string units MU0, MU2, MU3 and MU4 are failure regions, and other string units MU1, MU5 are good regions.

Accordingly, the string units MU1, MU5 become usable regions for writing data. The explanation whether or not the string units MU6 to MU11 are failure regions is omitted.

### 1. 3<Circuit Diagram of Block Decoder BD>

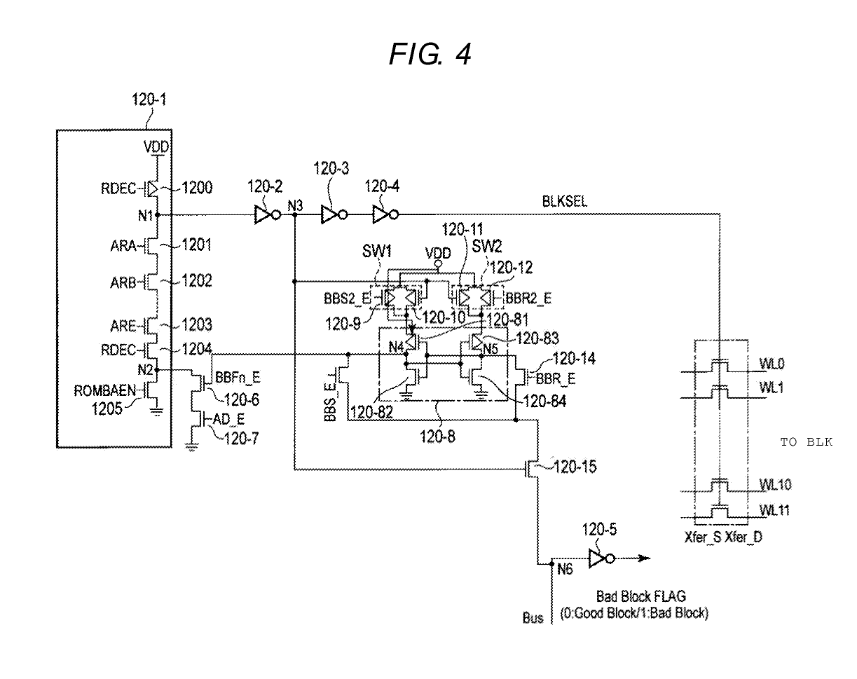

Next, the circuit of the block decoder BD is described with reference to a circuit diagram shown in FIG. 4.

As shown in FIG. 4, the block decoder BD includes a decode section 120-1, inverters 120-2 to 120-5, n-channel MOS transistors 120-6, 120-7, a latch section 120-8, p-channel MOS transistors 120-9 to 120-12, and n-channel MOS transistors 120-13 to 120-15.

### 1. 3. 1<in Re Decode Section 120-1>

The decode section 120-1 includes a p-channel MOS transistor 1200, and n-channel MOS transistors 1201 to 1205.

A voltage VDD is supplied to one end of an electric current path of the MOS transistor 1200, a signal RDEC is supplied to a gate of the MOS transistor 1200, and the other end of the electric current path is connected to a node N1.

The MOS transistors 1201 to 1203 are connected to each other in series, and signals ARA to ARE are supplied to gates of the respective transistors 1201 to 1203.

Further, one end of an electric current path of the MOS transistor 1204 is connected to the other end of an electric current path of the MOS transistor 1203, the other end of the electric current path of the MOS transistor 1204 is connected to a node N2, and a signal RDEC is supplied to a gate of the MOS transistor 1204.

One end of an electric current path of the MOS transistor 1205 is connected to a node N2, the other end of the electric current path of the MOS transistor 1205 is connected to the ground, and a signal ROMBAEN is supplied to a gate of the MOS transistor 1205.

The decode section 120-1 includes the MOS transistors 1200 to 1205, and when all of the signals ARA to ARE, the signal RDEC and the signal ROMBAEN are at “H” level, the node N1 is connected to the ground to be at “L” level.

On the other hand, when the node N1 is not connected to the ground, the node N1 maintains “H” level. As described above, the decode section 120-1 outputs a voltage of a voltage level at the node N1 to the inverter 120-2 as described later.

### 1. 3. 2< in Re Inverters 120-2 to 120-4>

The inverter 120-2 inverts a voltage level at an input end (node N1), and outputs an inverted voltage to the node N3.

The inverter 120-3 inverts a voltage level at the node N3.

The inverter 120-4 further inverts a voltage level of the voltage output from the inverter 120-3, and outputs a voltage of an inverted voltage level to the Xfer_S and the Xfer_D as a signal BLKSEL.

When the signal BLKSEL is at “H” level, MOS transistors in the Xfer_S and the Xfer_D respectively are in an ON state.

Due to such an operation, the corresponding block BLK is selected. The block decoder BD is provided for every block BLK.

### 1. 3. 3< in Re Switch SW1>

The switch SW1 includes MOS transistors 120-9, 120-10.

A voltage VDD is supplied to one end of an electric current path of the MOS transistor 120-9 and one end of an electric path of the MOS transistor 120-10, the other end of the electric current path of the MOS transistor 120-9 and the other end of the electric current path of the MOS transistor 120-10 are connected to one end of an electric current path of a MOS transistor 120-81 described later, a signal BBS2_E is supplied to a gate of the MOS transistor 120-9, and a gate of the MOS transistor 120-10 is connected to the node N3.

That is, the MOS transistors 120-9, 120-10 are turned on or off in accordance with a voltage level of the node N3 and a voltage level of the signal BBS2_E.

### 1. 3. 4< in Re Switch SW2>

The switch SW2 includes MOS transistors 120-11, 120-12.

A voltage VDD is supplied to one end of an electric current path of the MOS transistor 120-11 and one end of an electric current path of the MOS transistor 120-12, and the other end of the electric current path of the MOS transistor 120-11 and the other end of the electric current path of the MOS transistor 120-12 are connected to one end of an electric current path of a MOS transistor 120-83 described later, a gate of the MOS transistor 120-11 is connected to the node N3, and a signal BBR2_E is supplied to a gate of the MOS transistor 120-12.

That is, the MOS transistors 120-11, 120-12 are turned on or off in accordance with a voltage level of the node N3 and a voltage level of the signal BBS2_E.

### 1. 3. 5< in Re Latch Section 120-8>

The latch section 120-8 includes MOS transistors 120-81 to 120-84.

The other end of an electric current path of the MOS transistor 120-81 is connected to one end of an electric current path of the MOS transistor 120-82 at a node N4 (output end), and a node N5 (input end) is connected to a gate of the MOS transistor 120-81.

The other end of the electric current path of the MOS transistor 120-82 is connected to the ground, and a gate of the MOS transistor 120-82 is connected to the node N5.

The other end of an electric current path of the MOS transistor 120-83 is connected to one end of an electric current path of the MOS transistor 120-84 at the node N5 (output end), and a gate of the MOS transistor 120-83 is connected to the node N4.

The other end of an electric current path of the MOS transistor 120-84 is connected to the ground, and a gate of the MOS transistor 120-84 is connected to the node N4.

Data held by the latch section 120-8 takes a value corresponding to a voltage level at the node N5, and a voltage level at the node N4 is a voltage level of inverted data at the node N5.

### 1. 3. 6< in Re MOS Transistors 120-13 to 120-15>

One end of an electric current path of the MOS transistor 120-13 is connected to the node N4, and a signal BBS_E is supplied to a gate of the MOS transistor 120-13.

One end of an electric current path of the MOS transistor 120-14 is connected to the node N5, the other end of the electric current path of the MOS transistor 120-14 is connected to the other end of the electric current path of the MOS transistor 120-13 in common, and a signal BBR_E is supplied to a gate of the MOS transistor 120-14.

One end of an electric current path of the MOS transistor 120-15 is connected to the above-mentioned MOS transistors 120-13, 120-14, the other end of the electric current path of the MOS transistor 120-15 is connected to a selector bus, and a gate of the MOS transistor 120-15 is connected to the node N3.

The inverter 120-5 outputs a voltage of a voltage level at a node N6 to the control circuit 15. When a voltage level of a voltage output from the inverter 120-5 is “L” level, the control circuit 15 recognizes that the block BLK is a good block. When the voltage level of the voltage output from the inverter 120-5 is “H” level, the control circuit 15 recognizes that the block BLK is a bad block.

### 2. In Re Partial Good Block Determination Operation

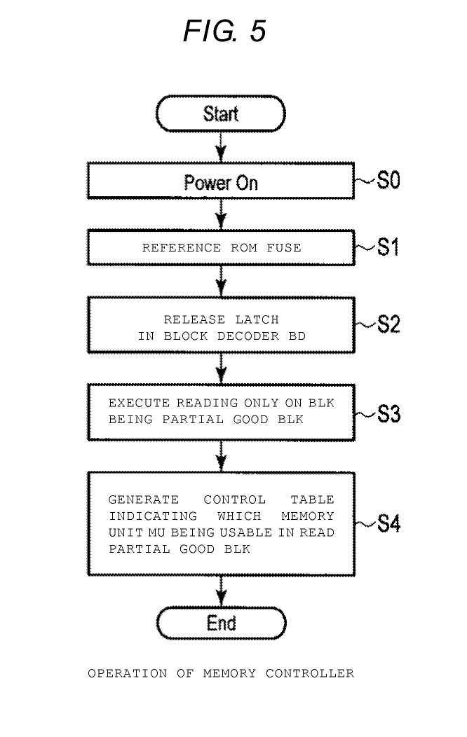

Next, with reference to FIG. 5, the description is made with respect to a method of determining which block is a partial good block BLK in the Plane by the memory controller 2.

The block BLK which partially includes a usable region is referred to as a partial good block BLK hereinafter.

FIG. 5 shows the flow of an operation of the memory controller 2 when the semiconductor device 100 is activated with the supply of power.

When the semiconductor device 100 is activated with the supply of power (step S0), the memory controller 2 refers to a ROM FUSE. To be more specific, the memory controller 2 refers to a block address BA including partial bad blocks in the ROM FUSE described later. (S1)

Due to such an operation, the memory controller 2 may recognize which block BLK includes a partial bad block.

Next, the memory controller 2 resets (releases) the latch section 120-8 in the corresponding block decoder BD based on the block address BA which the memory controller 2 recognizes in step S1 (S2).

Thereafter, the memory controller 2 executes a reading operation on the block BLK including partial good blocks, that is, on the block BLK corresponding to the block decoder BD in which the latch section 120-8 is released (S3). To be more specific, the memory controller 2 reads data held by the select transistors ST1 of the memory strings MS1 to MS12 in the block BLK including a partial bad block.

As a result of such a reading operation, when read data is “0” data, the memory controller 2 recognizes that the memory string MS is a partial good block.

By executing the above-mentioned reading operation, the memory controller 2 recognizes which memory unit MU is a good block, and generates a control table based on the result of recognition (S4).

The control table may be held by the memory controller 2 or by the control circuit 15.

A method of reading data held by the select transistor ST1 is described in Japanese Patent Application No. 2012-208786 filed on Sep. 21, 2012 (semiconductor storage device), for example. The entire contents of the patent application are incorporated herein by reference.

### 3. <Schematic Diagram of ROM FUSE>

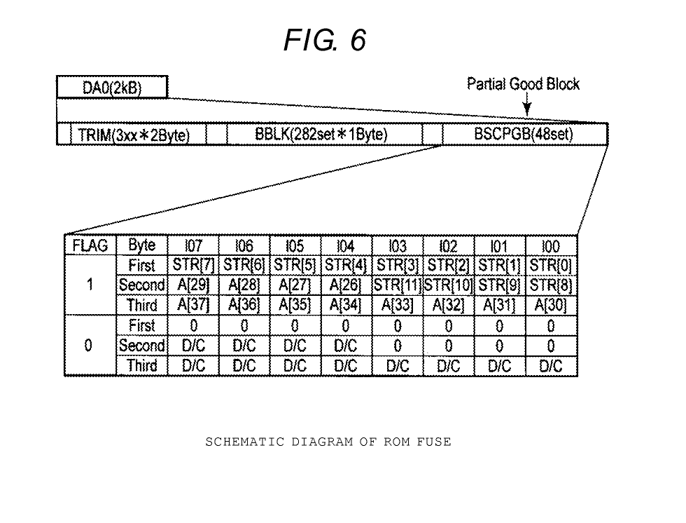

Next, the ROM FUSE is described with reference to FIG. 6 which is a schematic diagram of the ROM FUSE.

As shown in FIG. 6, the ROM. FUSE holds information which is roughly classified into bad block BLK information (BBLK in the drawing) and partial good block BLK information (BSCPGB (Bad String Chunk Partial Good Block)).

The BSCPGB includes 48 sets of failure information, and is classified into an address where a value of FLAG is set to “0”, and an address where a value of FLAG is set to “1”. FLAG means a value indicating whether or not a block is a bad block. For example, FLAG “1” indicates a bad block, and FLAG “0” indicates a good block.

As shown in FIG. 6, First, Second, and Third are represented on an axis of ordinates, and 100 to 107 are represented on an axis of abscissas.

Here, First, Second, Third indicate the order that data is read from the ROM FUSE, and 100 to 107 indicate output pins from which an address is output to the memory controller 2. That is, address data of 8-bit is read by the memory controller 2 in order from the First row to the Third row.

Here, symbol “STR” in the First row indicates an address of a memory string MS in a certain block BLK, and symbol “A” indicates an address of a bad block.

The controller 2 recognizes which block is a block BLK including a partial good block by reading the addresses in the ROM FUSE.

### 4. Method of Resetting Block Decoder BD

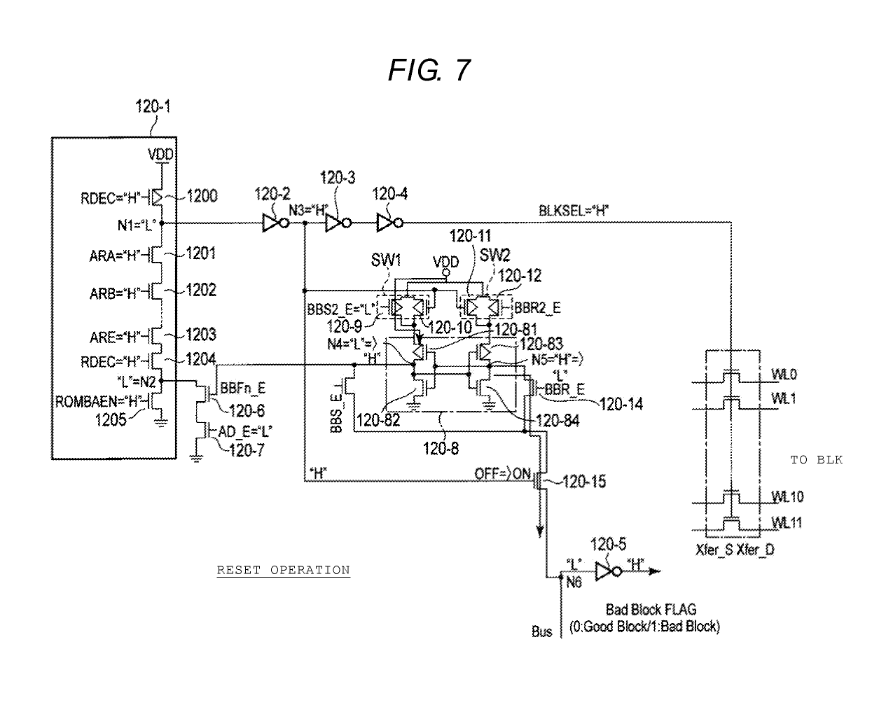

A method of resetting (releasing) the block decoder BD using the memory controller 2 in the above-mentioned step S2 is described with reference to FIG. 7. The control circuit 15 may reset the block decoder BD.

As described above, when a voltage level at the node N5 is data held by the latch section 120-8, and when the corresponding block BLK is a bad block, a voltage level at the node N5 is at “H” level.

To the contrary, when the corresponding block BLK is a good block BLK, for example, the voltage level at the node N5 is at “L” level.

Hereinafter, the method of resetting block decoder BD is described.

When the memory controller 2 recognizes that the block BLK includes a partial good block in the above-mentioned step S1, the memory controller sets a voltage level at the node N1 in the block decoder BD to “L” as shown in FIG. 7.

That is, the signals ARA to ARE, the signal RDEC, and the signal ROMBAEN is at “H” level so that the node N1 is connected to the ground.

Accordingly, the inverter 120-2 outputs a voltage of “H” level to the node N3. As a result, the MOS transistor 120-15 whose gate is connected to the node N3 is at an ON state so that the node N5 is shifted from previous “H” level to “L” level through the node N6, the MOS transistor 120-15 and the MOS transistor 120-14.

As a result, the latch section 120-8 holds “L” level, that is, a voltage of the same value as a voltage level indicating that a block BLK is a good block BLK.

### 5. <Reading Operation>

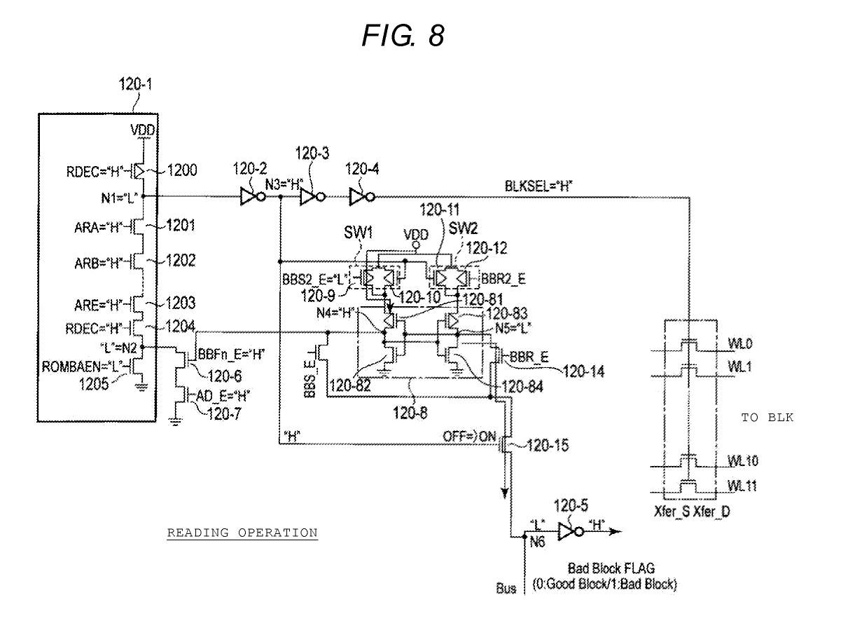

Next, the reading operation in step S3 is described with reference to FIG. 8. The reading operation may be controlled by the memory controller 2 or the control circuit 15.

In the reading operation, the signals ARA to ARE, and the signal RDEC are at “H” level, and the signal ROMBAEN is at “L” level.

As described above, in step S2, the latch section 120-8 holds “L” level. Accordingly, in the reading operation executed on the partial good block in step S3, the MOS transistor 120-6 is at an ON state, and the signal AD_E is at “H” level. Accordingly, the node N2 is at a ground potential through the MOS transistors 120-6, 120-7. Accordingly, the node N1 is at “L” level.

As a result, the inverter 120-4 outputs a signal BLKSEL of “H” level. That is, the MOS transistors in the Xfer_S and the Xfer_D are in at an ON state so that a read voltage may be transferred to the corresponding block BLK.

That is, the memory controller 2 may execute the reading operation on the block BLK which includes a partial good block.

The other end of the electric current path of the MOS transistor 120-15 at this time is connected to the ground through a bus, and a signal BBR_E is at “H” level and hence, the MOS transistor 120-14 is in an ON state.

The inverter 120-5 inverts a voltage level of a voltage at the node N5, and outputs the inverted voltage level of the voltage to the memory controller 2 as a bad block flag BF.

As shown in FIG. 8, when the bad block flag BF is at “H” level, the memory controller 2 recognizes that the reading operation is executed on the bad block.

The explanation has been made heretofore with reference to FIG. 8 with respect to the block decoder BD when a reading operation is executed on the block BLK which includes the partial good block. However, the reading operation is not executed on the block BLK which includes no partial good block. Accordingly, any one of the signals ARA to ARE, the signal RDEC, and the signal ROMBAEN is at “L” level. As a result, a potential at the node N3 is held at “L” level.

### Advantageous Effect of this Embodiment

In the semiconductor device according to this embodiment, following advantageous effects (1) and (2) may be realized.

(1) It is possible to increase a usable memory region while suppressing the increase of a latch region.

Conventionally, an address indicating a partial good block is stored in a dedicated latch region.

However, in this embodiment, the block address BA including a partial good block is stored in the ROM FUSE, and information which indicates that a block is a bad block in units of memory string unit MU is stored in the select transistor ST.

That is, it becomes unnecessary to provide a latch region for storing an address of a partial good block.

However, although the memory controller 2 may recognize the block BLK which includes a partial good block, the memory controller 2 may not recognize which memory string unit MU is good and which memory string unit MU is bad.

However, in the semiconductor device 100 according to this embodiment, after executing a reset operation of the block decoder BD in step S2, it is possible to read which memory string unit MU is bad in the block BLK and generate a control table based on the result of the reading operation.

Accordingly, the memory controller 2 may determine a region which is a partial good block without providing the latch region used conventionally, and may increase a memory region as described above.

(2) It is possible to use also the related memory controller.

When a partial good block is not used in a region, the region is recognized as a bad block.

That is, it is sufficient to use only a memory controller of prior art without using the memory controller described in this embodiment.

When the related memory controller is used, it is sufficient to store only a block address BA which indicates a bad block in the ROM FUSE and hence, the handling of the semiconductor device 1 upon shipping may be facilitated.

Accordingly, it is possible to increase a usable memory region without increasing the above-mentioned latch region where an address indicating a partial good block is stored.

### <Modification>

Next, a semiconductor device according to a modification of the above-mentioned embodiment is described. The semiconductor device 100 according to the modification differs from the above-mentioned semiconductor device in a point that a memory controller 2 holds a dedicated command for releasing a latch section 120-8, for example.

To be more specific, in the above-mentioned embodiment, a partial good block is retrieved simultaneously with the activation of the semiconductor device 100. However, the modification differs from the above-mentioned embodiment in that a partial good block is retrieved when a dedicated command is issued from the memory controller 2, for example. That is, upon activating the semiconductor device 100, the memory controller 2 recognizes that a block BLK0 and a block BLK4 shown in FIG. 2B are bad blocks.

Hereinafter, the points which make the modification different from the embodiment are described. The dedicated command may be held by a control circuit 15 or by host equipment (not shown) which controls the semiconductor device 100.

### 1. In Re Dedicated Command

The dedicated command means a command for executing operations from step S1 to step S4 in the above-mentioned FIG. 5.

For example, in FIG. 2B, initially, a user may use only good blocks BLK such as the block BLK1 and the block BLK3. However, when capacity of data is increased or the like, a dedicated command may be issued on a user side, or a dedicated command may be spontaneously issued from the memory controller 2 at a point in time that a usable data capacity of the memory cell array 11 reaches a fixed level.

In the above-mentioned embodiment, the description is made with respect to the case where the plurality of select transistors ST which hold “C” data are present in the block BLK0 or the block BLK4 which is a partial good block. However, when the block BLK2 is used, all select transistors ST1 constituting the memory strings MS0 to MS11 hold “C” data, for example.

As described above, bad block information is also stored in the ROM FUSE and hence, it is unnecessary to hold “C” data in all select transistors ST1 in the block BLK2, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor storage device comprising:
a memory cell array including a plurality of memory strings, the memory cell array divided into blocks, each of which is a erasable unit, the blocks including a first block which is determined to be a bad block and a second block which is determined to be a partial bad block;
a storage unit configured to store address information of the first block and the second block; and
a block decoder including a latch section which is configured to control selection and non-selection of the blocks, and to release data held by the latch section based on the stored address information of the second block.

2. The non-volatile semiconductor storage device according to claim 1, wherein
a threshold level of a select transistor which makes up the memory string and controls ON and OFF for selecting the memory string in the second block determines whether or not the memory string is bad.

3. The non-volatile semiconductor storage device according to claim 2, wherein
the select transistor has an increased threshold level to indicate that the memory string is bad.

4. The non-volatile semiconductor storage device according to claim 2, wherein
the select transistor has a threshold level corresponding to an erased state to indicate that the memory string is good.

5. The non-volatile semiconductor storage device according to claim 2, wherein the memory cell array includes a plurality of bit lines and the select transistor is connected between one of the bit lines and memory cells of the memory string.

6. The non-volatile semiconductor storage device according to claim 1, wherein the storage unit comprises a ROM FUSE unit.

7. A semiconductor device comprising:
a non-volatile semiconductor storage device including
a memory cell array including a plurality of memory strings, the memory cell array divided into blocks, each of which is a erasable unit, the blocks including a first block which is determined to be a bad block and a second block which is determined to be a partial bad block,
a storage unit configured to store address information of the first block and the second block, and
a block decoder including a latch section which is configured to control selection and non-selection of the blocks, and to release data held by the latch section based on the stored address information of the second block; and
a memory controller configured to control the non-volatile semiconductor storage device, and maintain a control table that indicates that memory strings in the second block that are good or bad.

8. The semiconductor device according to claim 7, wherein
the memory controller is configured to access the storage unit to determine if the second block is a partial bad block, and releases the data held by the latch section in the block decoder to select the second block if the second block is a partial bad block.

9. The semiconductor device according to claim 7, wherein
the memory controller is configured to access the storage unit to determine if the second block is a partial bad block, and does not release the data held by the latch section in the block decoder to select the second block if the second block is a bad block.

10. The semiconductor device according to claim 7, wherein
the memory controller is configured to access the storage unit to identify a partial bad block, and release the data held by the latch section in the block decoder to select the partial bad block.

11. The semiconductor device according to claim 7, wherein
the memory controller is configured to release the data held by the latch section in the block decoder to select a partial bad block if a dedicated command to select the partial bad block is received.

12. The semiconductor device according to claim 11, wherein the dedicated command is issued when a usable data capacity of the memory cell array reaches a fixed level.

13. The semiconductor device according to claim 7, wherein
a threshold level of a select transistor which makes up the memory string and controls ON and OFF for selecting the memory string in the second block determines whether or not the memory string is bad.

14. The semiconductor device according to claim 13, wherein
the select transistor has an increased threshold level to indicate that the memory string is bad.

15. The semiconductor device according to claim 13, wherein
the select transistor has a threshold level corresponding to an erased state to indicate that the memory string is good.

16. The semiconductor device according to claim 13, wherein the memory cell array includes a plurality of bit lines and the select transistor is connected between one of the bit lines and memory cells of the memory string.

17. The semiconductor device according to claim 7, wherein the storage unit comprises a ROM FUSE unit.

18. A method of determining usable regions of a partial bad block in a non-volatile semiconductor storage device, comprising:
accessing a storage unit that stores address information of a partial bad block;
releasing data held by a latch section in a block decoder to select the partial bad block based on the stored address information of the partial bad block;
reading data held by select transistors of the partial bad block to determine good memory strings and bad memory strings; and
updating a control table to indicate the memory strings that are good and the memory strings that are bad.

19. The method of claim 18, wherein the select transistor of a memory string has an increased threshold level to indicate that the memory string is bad, and a threshold level corresponding to an erased state to indicate that the memory string is good.

20. The method of claim 19, wherein the select transistors holding the data that are read, are each connected between a bit line and a memory string.
